(19) United States
(12) Patent Application Publication
(10) Pub. No.: US 2024/0421212 A1
(43) Pub. Date: Dec. 19, 2024

(54) SEMICONDUCTOR DEVICES

(71) Applicant: Samsung Electronics Co., Ltd., Suwon-si (KR)

(72) Inventors: Woo Seok Park, Suwon-si (KR); Jae Ho Jeon, Suwon-si (KR); Sung Gi Hur, Suwon-si (KR)

(21) Appl. No.: 18/642,987

(22) Filed: Apr. 23, 2024

(30) Foreign Application Priority Data
Jun. 13, 2023 (KR) 10-2023-0075603

(51) Int. Cl. H01L 29/66; H01L 29/06

(52) U.S. Cl. CPC H01L 29/66553; H01L 29/0673

(57) ABSTRACT

There is provided a semiconductor device capable of improving element performance and reliability. The semiconductor device may include an active pattern that includes a lower pattern extending in a first direction on a substrate and a sheet pattern on the lower pattern, a field insulating layer that defines the active pattern on the substrate, a gate structure on the lower pattern and including a gate insulating layer and a gate electrode, the gate electrode extending in a second direction perpendicular to the first direction, a gate spacer at least partially surrounding the gate structure and including a first portion on a sidewall of the gate structure and a second portion on a bottom surface of the gate structure, and a source/drain pattern on the lower pattern and in contact with the sheet pattern.

### CROSS-REFERENCE TO RELATED APPLICATION

This application claims priority from Korean Patent Application No. 10-2023-0075603 filed on Jun. 13, 2023 in the Korean Intellectual Property Office, and all the benefits accruing therefrom under 35 U.S.C. 119, the contents of which in its entirety are herein incorporated by reference.

### BACKGROUND

The present disclosure relates to semiconductor devices, and more particularly, to semiconductor devices including a multi-bridge channel field effect transistor (MBCFET™).

As one of the scaling techniques for increasing the density of semiconductor devices, a multi-gate transistor has been proposed, in which a fin-or nanowire-shaped multi-channel active pattern (or silicon body) is formed on a substrate and a gate is formed on the surface of the multi-channel active pattern.

Since the multi-gate transistor uses a three-dimensional (3D) channel, scaling of the multi-gate transistor can be easily achieved. Further, current control capability can be improved without increasing the gate length of the multi-gate transistor. In addition, a short channel effect (SCE) in which the potential of a channel region is affected by a drain voltage can be effectively suppressed.

### SUMMARY

Aspects of the present disclosure provide semiconductor devices capable of improving element performance and reliability.

However, aspects of the present disclosure are not restricted to the ones set forth herein. The above and other aspects of the present disclosure will become more apparent to one of ordinary skill in the art to which the present disclosure pertains by referencing the detailed description of the present disclosure given below.

According to some embodiments of the present disclosure, there is provided a semiconductor device including an active pattern that includes a lower pattern extending in a first direction on a substrate and a sheet pattern on the lower pattern, a field insulating layer that defines the active pattern on the substrate, a gate structure on the lower pattern and including a gate insulating layer and a gate electrode, the gate electrode extending in a second direction perpendicular to the first direction, a gate spacer at least partially surrounding the gate structure and including a first portion on a sidewall of the gate structure and a second portion on a bottom surface of the gate structure, and a source/drain pattern on the lower pattern and in contact with the sheet pattern.

According to some embodiments of the present disclosure, there is provided a semiconductor device including a plurality of active patterns, each of the active patterns including a lower pattern extending in a first direction on a substrate and a sheet pattern on the lower pattern, a field trench defined by a top surface of the substrate and a sidewall of the lower pattern, a field insulating layer in the field trench, a gate structure on the lower pattern and including a gate insulating layer and a gate electrode, the gate electrode extending in a second direction perpendicular to the first direction, a gate spacer including a first portion that extends in a third direction perpendicular to the second direction along a sidewall of the gate structure and a second portion that extends in the first direction along a top surface of the field insulating layer, a source/drain pattern on the lower pattern and in contact with the sheet pattern, and a first interlayer insulating layer on the field insulating layer and the source/drain pattern and on one side of the gate structure.

According to some embodiments of the present disclosure, there is provided a semiconductor device including an active pattern that includes a lower pattern extending in a first direction on a substrate and a sheet pattern on the lower pattern, a field insulating layer that defines the active pattern on the substrate, a gate structure on the lower pattern and including a gate insulating layer and a gate electrode, the gate electrode extending in a second direction perpendicular to the first direction, a gate spacer at least partially surrounding the gate structure and including a first portion on a sidewall of the gate structure and a second portion on a bottom surface of the gate structure, a source/drain pattern on the lower pattern and in contact with the sheet pattern, and a first interlayer insulating layer on the field insulating layer and the source/drain pattern and extending in the second direction. The second portion of the gate spacer may be between the field insulating layer and the gate structure, and may not be between the field insulating layer and the first interlayer insulating layer.

### BRIEF DESCRIPTION OF THE DRAWINGS

The above and other aspects and features of the present disclosure will become more apparent by describing in detail example embodiments thereof with reference to the attached drawings, in which:

FIG. 1 is an example plan view illustrating a semiconductor device according to some embodiments.

FIG. 2 is an example cross-sectional view taken along line A-A of FIG. 1.

FIG. 3 is an example cross-sectional view taken along line B-B of FIG. 1.

FIG. 4 is an example cross-sectional view taken along line C-C of FIG. 1.

FIG. 5 is an example cross-sectional view taken along line D-D of FIG. 1.

FIGS. 6 to 8 are diagrams illustrating a semiconductor device according to some embodiments.

FIG. 9 is a diagram illustrating a semiconductor device according to some embodiments.

FIG. 10 is a diagram illustrating a semiconductor device according to some embodiments.

FIG. 11 is a diagram illustrating a semiconductor device according to some embodiments.

FIG. 12 is a diagram illustrating a semiconductor device according to some embodiments.

FIGS. 13 to 32 are diagrams illustrating the intermediate steps of a method for fabricating a semiconductor device according to some embodiments.

### DETAILED DESCRIPTION

A semiconductor device according to some embodiments may include a tunneling field effect transistor (FET), a three-dimensional (3D) FET or a two-dimensional (2D) material based FET, and a heterostructure thereof. Further, the semiconductor device according to some embodiments may include a bipolar junction transistor (BJT), a lateral double diffusion MOS (LDMOS) transistor, or the like.

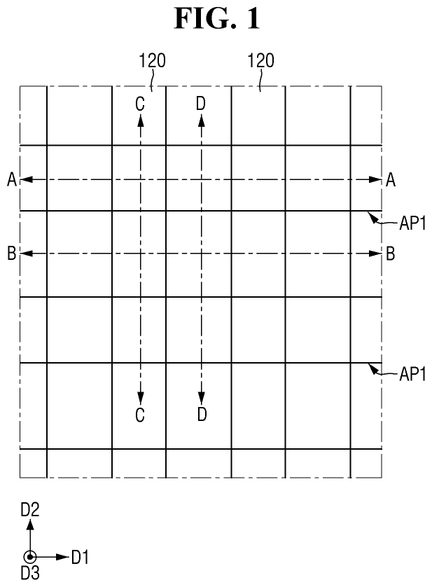

A semiconductor device according to some embodiments will be described with reference to FIGS. 1 to 5.

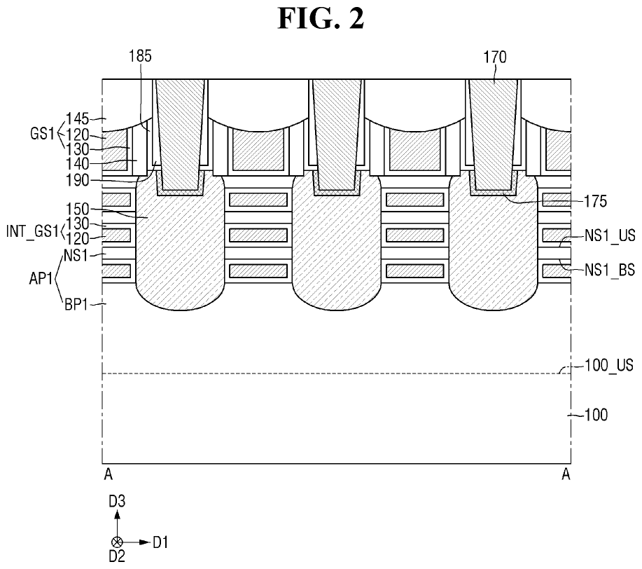

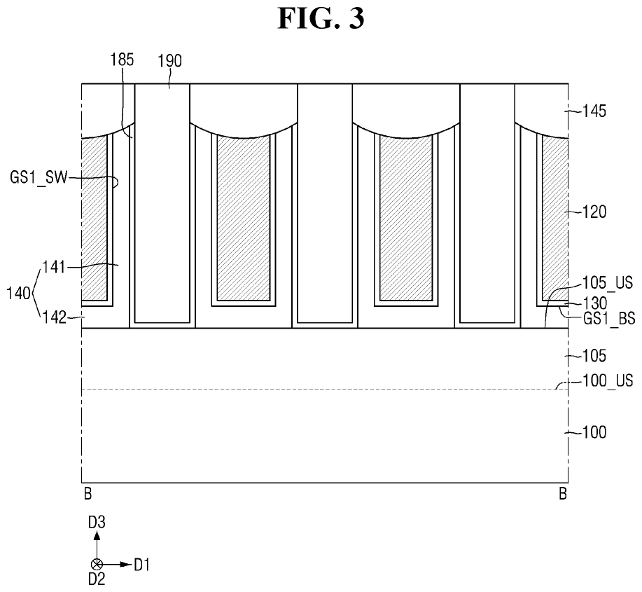

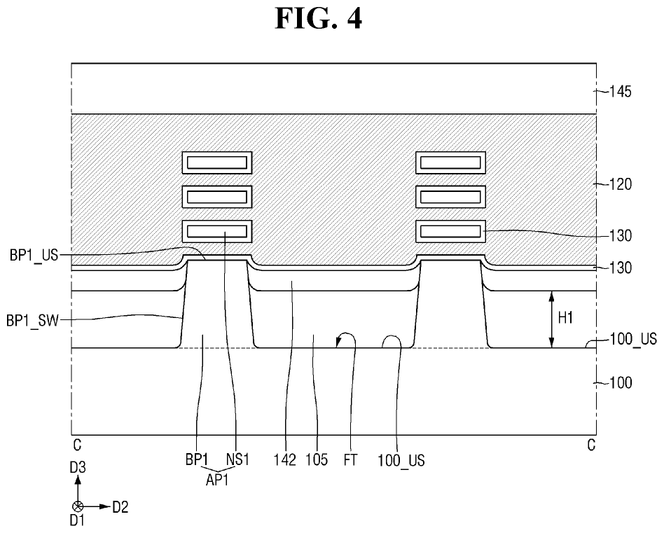

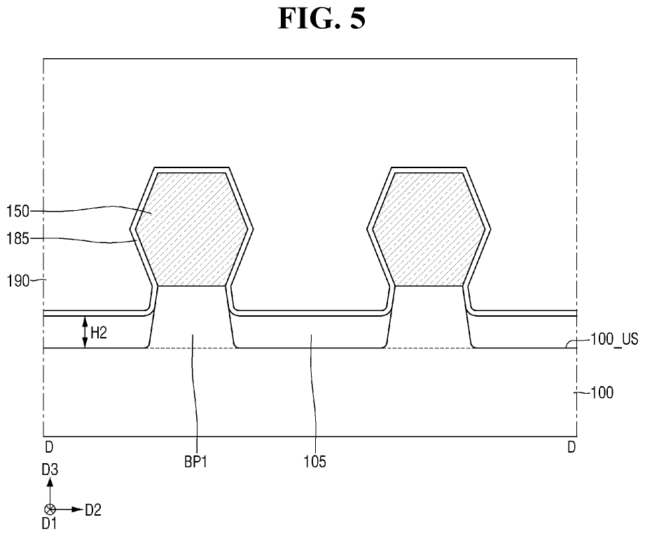

FIG. 1 is an example plan view illustrating a semiconductor device according to some embodiments. FIG. 2 is an example cross-sectional view taken along line A-A of FIG. 1. FIG. 3 is an example cross-sectional view taken along line B-B of FIG. 1. FIG. 4 is an example cross-sectional view taken along line C-C of FIG. 1. FIG. 5 is an example cross-sectional view taken along line D-D of FIG. 1.

FIG. 1 is a simplified view excluding a gate capping pattern 145, a gate spacer 140, a source/drain contact 170, an etch stop layer 185, a first interlayer insulating layer 190, and the like.

Referring to FIGS. 1 to 5, the semiconductor device according to some embodiments may include a substrate 100, an active pattern AP1, a plurality of gate structures GS1, a gate spacer 140, and a source/drain pattern 150.

The substrate 100 may be a bulk silicon or silicon-on-insulating layer (SOI) substrate. Alternatively, the substrate 100 may be a silicon substrate, or may include other materials such as silicon germanium, silicon germanium on insulating layer (SGOI), indium antimonide, a lead tellurium compound, indium arsenide, indium phosphide, gallium arsenide, or gallium antimonide, but is not limited thereto.

The active pattern AP1 may be disposed on the substrate 100. The active pattern AP1 may be elongated in a first direction D1. The active patterns AP1 may be spaced apart from each other in a second direction D2. The active patterns AP1 may be arranged in the second direction D2. For example, the first direction D1 is a direction crossing the second direction D2.

For example, the active pattern AP1 may be disposed in a region where a PMOS is formed. For another example, the active pattern AP1 may be disposed in a region where an NMOS is formed.

The active pattern AP1 may be a multi-channel active pattern. The active pattern AP1 may include a lower pattern BP1 and a plurality of sheet patterns NS1. The lower pattern BP1 may protrude from the substrate 100. The lower pattern BP1 may be elongated in the first direction D1. For example, the lower pattern BP1 may extend longitudinally in the first direction D1.

The lower patterns BP1 may be spaced apart from each other in the second direction D2. The lower patterns BP1 may be separated from each other by a field trench FT extending in the first direction D1. The field trench FT may be defined by a sidewall BP1_SW of the lower pattern BP1 and a top surface 100_US of the substrate 100.

A plurality of sheet patterns NS1 may be disposed above the lower pattern BP1. The plurality of sheet patterns NS1 may be spaced apart from the lower pattern BP1 in a third direction D3. The plurality of sheet patterns NS1 spaced apart from each other may be arranged along the top surface of the lower pattern BP1 in the first direction D1.

The sheet pattern NS1 may include a plurality of nanosheets sequentially disposed in the third direction D3. Each sheet pattern NS1 may include a top surface NS1_US and a bottom surface NS1_BS (e.g., see FIG. 2). The top surface NS1_US of the first sheet pattern is opposite to the bottom surface NS1_BS of the first sheet pattern in the third direction D3. The top surface NS1_US of the sheet pattern NS1 may be connected to the bottom surface NS1_BS of the sheet pattern NS1 via a connection surface of the sheet pattern NS1. The connection surface of the sheet pattern NS1 may be connected to and in contact with the source/drain pattern 150 which will be described later. The connection surface of the sheet pattern NS1 may be a boundary surface between the sheet pattern NS1 and the source/drain pattern 150.

The third direction D3 may intersect the first direction D1 and the second direction D2. For example, the third direction D3 may be a thickness direction of the substrate 100. The first direction D1 may be a direction crossing the second direction D2. The third direction D3 may be perpendicular to the first direction D1 and the second direction D2. For example, the third direction D3 may be perpendicular to the top surface 100_US of the substrate 100.

The sheet pattern NS1 may include a plurality of sheet patterns NS1 (also referred to as sub-sheet patterns). For example, the plurality of sheet patterns NS1 may include a plurality of nanosheets, respectively. Although it is illustrated that three sheet patterns NS1 are arranged in the third direction D3, this is merely for simplicity of description and the present disclosure is not limited thereto. For example, the number of the sheet patterns NS1 may be four.

Each lower pattern BP1 may be formed by etching a part of the substrate 100, or may include an epitaxial layer grown from the substrate 100. Each lower pattern BP1 may include silicon or germanium, each of which is an elemental semiconductor material. In addition, each lower pattern BP1 may include a compound semiconductor, for example, a group IV-IV compound semiconductor or a group III-V compound semiconductor.

The group IV-IV compound semiconductor may be a binary compound or a ternary compound including at least two elements selected from the group consisting of carbon (C), silicon (Si), germanium (Ge) and tin (Sn), or the above-mentioned compound doped with a group IV element.

The group III-V compound semiconductor may be, for example, a binary compound, a ternary compound or a quaternary compound formed by combining at least one of aluminum (Al), gallium (Ga) or indium (In) which are group III elements with one of phosphorus (P), arsenic (As) or antimonium (Sb) which are group V elements.

The sheet pattern NS1 may include one of silicon or germanium, which is an elemental semiconductor material, a group IV-IV compound semiconductor, or a group III-V compound semiconductor. The sheet pattern NS1 may include the same material as the lower pattern BP1, or may include a material different from that of the lower pattern BP1.

In the semiconductor device according to some embodiments, the lower pattern BP1 may be a silicon lower pattern containing silicon, and the sheet pattern NS1 may be a silicon sheet pattern containing silicon.

Taking the active pattern AP1 as an example, the width of the first sheet pattern NS1 in the second direction D2 may increase or decrease in proportion to the width of the lower pattern BP1 in the second direction D2. In one example, although it is illustrated that the widths in the second direction D2 of the sheet patterns NS1 stacked in the third direction D3 are the same (e.g., see FIG. 4), this is merely for simplicity of description, and the present disclosure is not limited thereto. Unlike the illustrated example, the width in the second direction D2 of the sheet patterns NS1 stacked in the third direction D3 may decrease as the distance from the lower pattern BP1 increases.

A field insulating layer 105 may fill a part (i.e., a portion) of the field trench FT. For example, the field insulating layer 105 may be in the field trench FT. The field insulating layer 105 may be disposed between the adjacent lower patterns BP1. The field insulating layer 105 may extend in the first direction D1. The field insulating layer 105 may be formed on the top surface 100_US of the substrate 100. The field insulating layer 105 may cover a part of the sidewall BP1_SW of the lower pattern BP1. The field insulating layer 105 is not disposed on the top surface BP1_US of the lower pattern BP1. The top surface BP1_US of the lower pattern BP1 may protrude from the top surface of the field insulating layer 105 in the third direction D3. The field insulating layer 105 may define the active pattern AP1 on the substrate 100.

Each sheet pattern NS1 is disposed higher than the top surface of the field insulating layer 105. The field insulating layer 105 may include, for example, an oxide layer, a nitride layer, an oxynitride layer, or a combination layer thereof. Although the field insulating layer 105 is illustrated as being a single layer, this is only for simplicity of description, and the present disclosure is not limited thereto.

The plurality of gate structures GS1 may be disposed on the substrate 100. Each of the gate structures GS1 may extend in the second direction D2. The gate structures GS1 may be spaced apart from each other in the first direction D1. The gate structures GS1 may be adjacent to each other in the first direction D1.

The gate structure GS1 may be disposed on the active pattern AP1. The gate structure GS1 may cross the active pattern AP1.

The gate structure GS1 may cross the lower pattern BP1. The gate structure GS1 may surround each sheet pattern NS1. The gate structure GS1 may include, for example, a gate electrode 120 and a gate insulating layer 130.

Although it is illustrated that the gate structure GS1 is disposed over the active pattern AP1, this is merely for simplicity of description and the present disclosure is not limited thereto. That is, the gate structure GS1 may be separated into two parts, so that the gate structure GS1 intersecting one active pattern AP1 may be spaced from the gate structure GS1 intersecting another active pattern AP1 in the second direction D2.

The gate structure GS1 may include a plurality of first inner gate structures INT_GS1 disposed between ones of the sheet patterns NS1 adjacent in the third direction D3, and between the lower pattern BP1 and the sheet pattern NS1. The first inner gate structure INT_GS1 may be disposed between the top surface of the lower pattern BP1 and the bottom surface of the sheet pattern NS1, and between the top surface of the sheet pattern NS1 and the bottom surface of the sheet pattern NS1 that face each other in the third direction D3.

The number of the inner gate structures INT_GS1 may be the same as the number of the sheet patterns NS1. The inner gate structure INT_GS1 is in contact with the top surface of the lower pattern BP1, the top surface of the sheet pattern NS1, and the bottom surface of the sheet pattern NS1.

The inner gate structure INT_GS1 includes the first gate electrode 120 and the first gate insulating layer 130 disposed between the adjacent sheet patterns NS1 and between the lower pattern BP1 and the sheet pattern NS1.

In a semiconductor device according to some embodiments, the inner gate structure INT_GS1 may be in contact with the source/drain pattern 150 which will be described later. For example, the inner gate structure INT_GS1 may be in direct contact with the source/drain pattern 150. The inner gate structure INT_GS1 is in contact with the top surface BP1_US of the lower pattern BP1, the top surface NS1_US of the sheet pattern NS1, and the bottom surface NS1_BS of the sheet pattern NS1.

In a semiconductor device according to some embodiments, each of the inner gate structures INT_GS1 may have the same width in the first direction D1. The width of each inner gate structure INT_GS1 in the first direction D1 may be the same as the width of the sheet pattern NS1 in the first direction D1. However, the present disclosure is not limited thereto.

Unlike the drawing, in a semiconductor device according to some embodiments, the width of some inner gate structures INT_GS1 in the first direction D1 may be larger than the width of the adjacent inner gate structure INT_GS1 in the first direction D1.

The gate electrode 120 may be formed on the lower pattern BP1. The gate electrode 120 may intersect the lower pattern BP1. The gate electrode 120 may extend in the second direction D2. The gate electrode 120 may cover the sheet pattern NS1.

Taking the active pattern AP1 as an example, a part of the gate electrode 120 may be disposed between the adjacent sheet patterns NS1, and between the lower pattern BP1 and the sheet pattern NS1. When the sheet pattern NS1 includes a first sub-sheet pattern and a second sub-sheet pattern that are adjacent to each other in the third direction D3, a part of the gate electrode 120 may be disposed between the top surface NS1_US of the first sub-sheet pattern and the bottom surface NS1_BS of the second sub-sheet pattern that face each other. Further, a part of the gate electrode 120 may be disposed between the top surface BSI_US of the lower pattern BP1 and the bottom surface NS1_BS of the lowermost sheet pattern NS1. The first sub-sheet pattern may be the lowermost sheet pattern NS1, or may not be the lowermost sheet pattern NS1.

The gate electrode 120 may include at least one of a metal, a metal alloy, a conductive metal nitride, a metal silicide, a doped semiconductor material, a conductive metal oxide, or a conductive metal oxynitride. The gate electrode 120 may include, for example, at least one selected from the group consisting of titanium nitride (TiN), tantalum carbide (TaC), tantalum nitride (TaN), titanium silicon nitride (TiSiN), tantalum silicon nitride (TaSiN), tantalum titanium nitride (TaTiN), titanium aluminum nitride (TiAIN), tantalum aluminum nitride (TaAlN), tungsten nitride (WN), ruthenium (Ru), titanium aluminum (TiAl), titanium aluminum carbonitride (TiAlC—N), titanium aluminum carbide (TiAlC), titanium carbide (TiC), tantalum carbonitride (TaCN), tungsten (W), aluminum (Al), copper (Cu), cobalt (Co), titanium (Ti), tantalum (Ta), nickel (Ni), platinum (Pt), nickel platinum (Ni—Pt), niobium (Nb), niobium nitride (NbN), niobium carbide (NbC), molybdenum (Mo), molybdenum nitride (MoN), molybdenum carbide (MoC), tungsten carbide (WC), rhodium (Rh), palladium (Pd), iridium (Ir), osmium (Os), silver (Ag), gold (Au), zinc (Zn), vanadium (V) or a combination thereof. The conductive metal oxide and the conductive metal oxynitride may include a form in which the above-mentioned material is oxidized, but are not limited thereto.

The gate electrodes 120 may be disposed on both sides of the source/drain pattern 150 to be described later. The gate structures GS1 may be disposed on both sides of the source/drain pattern 150 in the first direction D1.

For example, the gate electrodes 120 disposed on both sides of the source/drain pattern 150 may be normal gate electrodes used as gates of transistors. As another example, the gate electrode 120 disposed on one side of the source/drain pattern 150 may be used as a gate of a transistor, whereas the gate electrode 120 disposed on the other side of the source/drain pattern 150 may be a dummy gate electrode.

The gate insulating layer 130 may extend along the top surface of the gate spacer 140 and the top surface BP1_US of the lower pattern BP1. The gate insulating layer 130 may cover the sheet pattern NS1. The gate insulating layer 130 may be disposed along the perimeter of the sheet pattern NS1. The gate electrode 120 is disposed on the gate insulating layer 130.

A part of the gate insulating layer 130 may be disposed between the sheet patterns NS1 adjacent in the third direction D3, and between the lower pattern BP1 and the sheet pattern NS1. When the sheet pattern NS1 includes the first sub-sheet pattern and the second sub-sheet pattern that are adjacent to each other, a part of the gate insulating layer 130 may extend along the top surface NS1_US of the first sub-sheet pattern and the bottom surface NS1_BS of the second sub-sheet pattern that face each other.

Although it is illustrated that the gate insulating layer 130 is a single layer, the present disclosure is not limited thereto. The gate insulating layer 130 may include an interfacial insulating layer and a high-k insulating layer. The interfacial insulating layer may be disposed between the high-k insulating layer and the sheet pattern NS1.

The gate insulating layer 130 may include silicon oxide, silicon oxynitride, silicon nitride, or a high-k material having a higher dielectric constant than silicon oxide. The high-k material may include, for example, at least one selected from the group consisting of boron nitride, hafnium oxide, hafnium silicon oxide, hafnium aluminum oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, lead scandium tantalum oxide, and lead zinc niobate.

The semiconductor device according to some embodiments may include a negative capacitor (NC) FET (i.e., an NC-FET) using a negative capacitor (NC). For example, the gate insulating layer 130 may include a ferroelectric material layer having ferroelectric properties and a paraelectric material layer having paraelectric properties.

The ferroelectric material layer may have a negative capacitance, and the paraelectric material layer may have a positive capacitance. For example, when two or more capacitors are connected in series and the capacitance of each capacitor has a positive value, the total capacitance becomes smaller than the capacitance of each capacitor. On the other hand, when at least one of the capacitances of two or more capacitors connected in series has a negative value, the total capacitance may have a positive value and may be greater than the absolute value of each capacitance.

When a ferroelectric material layer having a negative capacitance and a paraelectric material layer having a positive capacitance are connected in series, the total capacitance value of the ferroelectric material layer and the paraelectric material layer connected in series may increase. By using the principle that the total capacitance value is increased, the transistor containing the ferroelectric material layer may have a subthreshold swing (SS) lower than or equal to a threshold voltage of 60 mV/decade at room temperature.

The ferroelectric material layer may have ferroelectric properties. The ferroelectric material layer may include, for example, at least one of hafnium oxide, hafnium zirconium oxide, barium strontium titanium oxide, barium titanium oxide, or lead zirconium titanium oxide. In this case, as one example, the hafnium zirconium oxide may be a material containing hafnium oxide doped with zirconium (Zr). As another example, the hafnium zirconium oxide may be a compound of hafnium (Hf), zirconium (Zr), and oxygen (O).

The ferroelectric material layer may further include a dopant doped therein. For example, the dopant may include at least one of aluminum (Al), titanium (Ti), niobium (Nb), lanthanum (La), yttrium (Y), magnesium (Mg), silicon (Si), calcium (Ca), cerium (Ce), dysprosium (Dy), erbium (Er), gadolinium (Gd), germanium (Ge), scandium (Sc), strontium (Sr), or tin (Sn). The type of dopant included in the ferroelectric material layer may vary depending on which ferroelectric material is included in the ferroelectric material layer.

When the ferroelectric material layer includes hafnium oxide, the dopant included in the ferroelectric material layer may include, for example, at least one of gadolinium (Gd), silicon (Si), zirconium (Zr), aluminum (Al), or yttrium (Y).

When the dopant is aluminum (Al), the ferroelectric material layer may include 3 to 8 atomic percent (at %) of aluminum. In this case, the ratio of the dopant may be a ratio of aluminum to the sum of hafnium and aluminum.

When the dopant is silicon (Si), the ferroelectric material layer may include 2 to 10 at % of silicon. When the dopant is yttrium (Y), the ferroelectric material layer may include 2 to 10 at % of yttrium. When the dopant is gadolinium (Gd), the ferroelectric material layer may include 1 to 7 at % of gadolinium. When the dopant is zirconium (Zr), the ferroelectric material layer may include 50 to 80 at % of zirconium.

The paraelectric material layer may have paraelectric properties. The paraelectric material layer may include, for example, at least one of silicon oxide or metal oxide having a high dielectric constant. The metal oxide included in the paraelectric material layer may include, for example, at least one of hafnium oxide, zirconium oxide, or aluminum oxide, but is not limited thereto.

The ferroelectric material layer and the paraelectric material layer may include the same material. The ferroelectric material layer may have ferroelectric properties, but the paraelectric material layer may not have ferroelectric properties. For example, when the ferroelectric material layer and the paraelectric material layer include hafnium oxide, the crystal structure of the hafnium oxide included in the ferroelectric material layer is different from the crystal structure of the hafnium oxide included in the paraelectric material layer.

The ferroelectric material layer may have a thickness that exhibits ferroelectric properties. The thickness of the ferroelectric material layer may be, for example, in a range of 0.5 nanometers (nm) to 10 nm, but is not limited thereto. Since a critical thickness at which each ferroelectric material exhibits ferroelectric properties may be different, the thickness of the ferroelectric material layer may vary depending on the ferroelectric material.

In one example, the gate insulating layer 130 may include one ferroelectric material layer. In another example, the gate insulating layer 130 may include a plurality of ferroelectric material layers spaced apart from each other. The gate insulating layer 130 may have a laminated layer structure in which a plurality of ferroelectric material layers and a plurality of paraelectric material layers are alternately laminated.

In a semiconductor device according to some embodiments, the gate structure GS1 may further include the gate capping pattern 145. The gate capping pattern 145 may be disposed on the gate electrode 120, the gate insulating layer 130, and the gate spacer 140. For example, the gate capping pattern 145 may be on a top surface of the gate electrode 120. The top surface of the gate capping pattern 145 may lie on the same plane as (e.g., may be coplanar with) the top surface of a first interlayer insulating layer 190. Unlike the illustrated example, the gate capping pattern 145 may be disposed between the gate spacers 140.

The gate capping pattern 145 may include, for example, at least one of silicon nitride (SiN), silicon oxynitride (SiON), silicon carbonitride (SiCN), silicon oxycarbonitride (SiOCN), or a combination thereof. The gate capping pattern 145 may include, for example, a material having an etch selectivity with respect to the first interlayer insulating layer 190.

The gate spacer 140 may be disposed on the field insulating layer 105 and the active pattern AP1. The gate spacer 140 may surround the gate structure GS1. For example, the gate spacer 140 may surround a part of the gate structure GS1. The gate spacer 140 may extend along a sidewall GS1_SW of the gate structure GS1 in the second direction D2 (e.g., see FIG. 3). The gate spacer 140 may be disposed on the bottom surface GS1_BS of the gate structure GS1. It will be understood that “an element A surrounds an element B” (or similar language) as used herein means that the element A is at least partially around the element B but does not necessarily mean that the element A completely encloses the element B.

The gate spacer 140 may include a first portion 141 and a second portion 142. The first portion 141 of the gate spacer 140 may be defined as a portion disposed on the sidewall GS1_SW of the gate structure GS1. The second portion 142 of the gate spacer 140 may be defined as a portion disposed on the bottom surface GS1_BS of the gate structure GS1. The first portion 141 and the second portion 142 of the gate spacer 140 may be connected to each other to surround the gate structure GS1.

The first portion 141 of the gate spacer 140 may extend along the sidewall GS1_SW of the gate structure GS1 in the second direction D2 and the third direction D3. The gate capping pattern 145 may be disposed on the first portion 141 of the gate spacer 140. The first portion 141 of the gate spacer 140 may be disposed on the gate insulating layer 130 and the etch stop layer 185. The first portion 141 of the gate spacer 140 may be disposed between the gate structure GS1 and the first interlayer insulating layer 190.

The second portion 142 of the gate spacer 140 may be disposed on the bottom surface GS1_BS of the gate structure GS1. The second portion 142 of the gate spacer 140 may be disposed on the field insulating layer 105. The second portion 142 of the gate spacer 140 may extend along a top surface 105_US of the field insulating layer 105 in the first direction D1 (e.g., see FIG. 3).

The second portion 142 of the gate spacer 140 may be disposed adjacent to the first interlayer insulating layer 190. That is, the second portion 142 of the gate spacer 140 may overlap the first interlayer insulating layer 190 in the first direction D1. For example, a lower portion of the first interlayer insulating layer 190 may overlap the second portion 142 of the gate spacer 140 in the first direction D1. The second portion 142 of the gate spacer 140 may not be disposed between the first interlayer insulating layer 190 and the field insulating layer 105. The second portion 142 of the gate spacer 140 may not overlap the first interlayer insulating layer 190 in the third direction D3. That is, the second portion 142 of the gate spacer 140 may be free of overlap with the first interlayer insulating layer 190 in the third direction D3. For example, the first interlayer insulating layer 190 may be free of overlap with the gate spacer 140 in the third direction D3.

The second portion 142 of the gate spacer 140 may be disposed between the field insulating layer 105 and the gate structure GS1. The second portion 142 of the gate spacer 140 may not cover the top surface BP1_US of the lower pattern BP1. For example, the top surface BP1_US of the lower pattern BP1 may be free of the second portion 142 of the gate spacer 140 thereon. The second portion 142 of the gate spacer 140 does not overlap the sheet pattern NS1 in the third direction D3. That is, the second portion 142 of the gate spacer 140 may be free of overlap with the sheet pattern NS1 in the third direction D3. The second portion 142 of the gate spacer 140 is not disposed between the gate electrode 120 and the top surface NS1_US of the sheet pattern NS1. The second portion 142 of the gate spacer 140 is not disposed between the gate electrode 120 and the bottom surface NS1_BS of the sheet pattern NS1.

The second portion 142 of the gate spacer 140 may be disposed on a part of the sidewall BP1_SW of the lower pattern BP1 (e.g., see FIG. 4). The sidewall BP1_SW of the lower pattern BP1 may be completely covered by the field insulating layer 105 and the second portion 142 of the gate spacer 140. For example, the field insulating layer 105 may be on a first portion of the sidewall BP1_SW of the lower pattern BP1, and the second portion 142 of the gate spacer 140 may be on a second portion of the sidewall BP1_SW of the lower pattern BP1. The first and second portions of the sidewall BP1_SW of the lower pattern BP1 may be connected to each other. The sidewall BP1_SW of the lower pattern BP1 may be continuous. FIG. 4 illustrates the top portion of the second portion 142 of the gate spacer 140 as being lower than the top surface BP1_US of the lower pattern BP1, but the present disclosure is not limited thereto. For example, the top portion of the second portion 142 of the gate spacer 140 may be on the same plane as the top surface BP1_US of the lower pattern BP1.

The gate spacer 140 may include, for example, at least one of silicon nitride (SiN), silicon oxynitride (SiON), silicon oxide (SiO₂), silicon oxycarbonitride (SiOCN), silicon boron nitride (SiBN), silicon oxyboron nitride (SiOBN), silicon oxycarbide (SiOC) or a combination thereof. Although the gate spacer 140 is illustrated as being a single layer, this is merely for simplicity of description and the present disclosure is not limited thereto.

The field insulating layer 105 may include a first region that overlaps the gate structure GS1 in the third direction D3. The field insulating layer 105 may include a second region that overlaps the first interlayer insulating layer 190 in the third direction D3. The second portion 142 of the gate spacer 140 may be disposed in the first region of the field insulating layer 105, and may not be disposed in the second region thereof. The first region may be different from the second region. A height H1 of the first region of the field insulating layer 105 may be greater than a height H2 of the second region of the field insulating layer 105 (e.g., see FIGS. 4 and 5). For example, the height H1 may be a thickness of the first region of the field insulating layer 105 in the third direction D3, and the height H2 may be a thickness of the second region of the field insulating layer 105 in the third direction D3. In other words, a thickness H1 of the first region of the field insulating layer 105 in the third direction D3 may be greater than a thickness H2 of the second region of the field insulating layer 105 in the third direction D3. The second region of the field insulating layer 105 may be free of overlap with the gate structure GS1 in the third direction D3.

The source/drain pattern 150 may be disposed on the active pattern AP1. The source/drain pattern 150 may be disposed on the lower pattern BP1. The source/drain pattern 150 is connected (e.g., electrically connected) to the sheet pattern NS1. The source/drain pattern 150 is in contact with the sheet pattern NS1. The source/drain pattern 150 may connect the sheet patterns NS1 spaced apart in the first direction D1.

The source/drain pattern 150 may be disposed on at least one side of the gate structure GS1. The source/drain pattern 150 may be disposed between the gate structures GS1 that are adjacent in the first direction D1. For example, the source/drain patterns 150 may be disposed on both sides (e.g., opposing sides) of the gate structure GS1. Unlike the drawing, the source/drain pattern 150 may be disposed on one side of the gate structure GS1 and may not be disposed on the other side of the gate structure GS1.

The source/drain pattern 150 may be included in the source/drain of a transistor that uses the sheet pattern NS1 as a channel region.

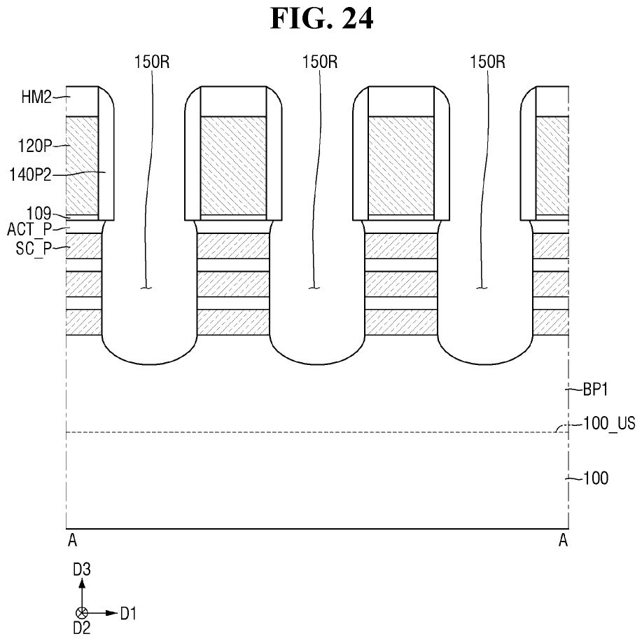

The source/drain pattern 150 may be disposed within a source/drain recess. A source/drain recess 150R extends in the third direction D3 (e.g., see FIG. 24). The source/drain recess may be defined between the gate structures GS1 that are adjacent in the first direction D1.

For example, the bottom surface of the source/drain recess may be defined by the lower pattern BP1. The sidewall of the source/drain recess may be defined by the sheet pattern NS1 and the inner gate structure INT_GS1. A part of the sidewall of the source/drain recess may be defined by the gate structure GS1 between the uppermost sheet patterns NS1. In a semiconductor device according to some embodiments, the sidewall of the inner gate structure INT_GS1 may be defined by the gate insulating layer 130 of the inner gate structure INT_GS1.

Between the lowermost sheet pattern NS1 and the lower pattern BP1, the boundary between the gate insulating layer 130 and the lower pattern BP1 may be the top surface BP1_US of the lower pattern BP1 (e.g., see FIG. 4). The bottom surface of the source/drain recess is lower than the top surface BP1_US of the lower pattern BP1.

The source/drain pattern 150 may be disposed in the source/drain recess. The source/drain pattern 150 may fill the source/drain recess.

The source/drain pattern 150 may be in contact with the sheet pattern NS1 and the lower pattern BP1. The inner gate structure INT_GS1 may be in contact with the source/drain pattern 150. Although the top surface of the source/drain pattern 150 is shown as being higher than the uppermost sheet pattern NS1, the present disclosure is not limited thereto. In some embodiments, unlike the drawing, the top surface of the source/drain pattern 150 may be disposed on the same plane as the top surface of the uppermost sheet pattern NS1, or may be disposed lower than the top surface thereof.

The source/drain pattern 150 may include an epitaxial pattern. The source/drain pattern 150 includes a semiconductor material.

The source/drain pattern 150 may include, for example, silicon or germanium, which is an elemental semiconductor material. In addition, the source/drain pattern 150 may be a binary compound or a ternary compound including at least two elements selected from the group consisting of carbon (C), silicon (Si), germanium (Ge) and tin (Sn), or the above-mentioned compound doped with a group IV element. For example, the source/drain pattern 150 may include silicon, silicon-germanium, germanium, silicon carbide, or the like, but the present disclosure is not limited thereto.

The source/drain pattern 150 may include impurities doped into a semiconductor material. The doped impurities may include, but are not limited to, at least one of boron (B), phosphorus (P), carbon (C), arsenic (As), antimony (Sb), bismuth (Bi), or oxygen (O).

Although the source/drain pattern 150 is illustrated as being a single layer, this is merely for simplicity of description and the present disclosure is not limited thereto.

Although the source/drain pattern 150 in contact with the inner gate structure INT_GS1 is illustrated as having the same width in the first direction D1, the present disclosure is not limited thereto.

Unlike the drawing, in a semiconductor device according to some embodiments, the width of the source/drain pattern 150 in the first direction D1 may increase and then decrease as it moves away from the lower pattern BP1 in the third direction D3.

Unlike the drawing, in a semiconductor device according to some embodiments, the width of the source/drain pattern 150 in the first direction D1 may be larger than the width of the etch stop layer 185 in the first direction D1. In this case, the width of the source/drain pattern 150 in the first direction D1 may be a distance between the sheet patterns NS1 that are adjacent in the first direction D1.

The etch stop layer 185 may extend along the sidewall of the gate capping pattern 145, the top surface of the field insulating layer 105, and the profile of the source/drain pattern 150.

The etch stop layer 185 may include a material having an etch selectivity with respect to the first interlayer insulating layer 190 which will be described later. The etch stop layer 185 may include, for example, at least one of silicon nitride (SiN), silicon oxide (SiO₂), silicon oxynitride (SiON), silicon oxycarbonitride (SiOCN), silicon boron nitride (SiBN), silicon oxyboron nitride (SiOBN), silicon oxycarbide (SiOC) or a combination thereof.

The first interlayer insulating layer 190 may be disposed on the etch stop layer 185. The first interlayer insulating layer 190 may be disposed on the source/drain pattern 150. The first interlayer insulating layer 190 may be disposed on one side of the gate structure GS1. The first interlayer insulating layer 190 may be disposed between the gate structures GS1. The first interlayer insulating layer 190 may be disposed on the field insulating layer 105. The first interlayer insulating layer 190 may extend in the second direction D2.

The first interlayer insulating layer 190 may include, for example, at least one of silicon oxide, silicon nitride, silicon oxynitride, or a low-k material. The low-k material may include, for example, fluorinated tetraethylorthosilicate (FTEOS), hydrogen silsesquioxane (HSQ), bis-benzocyclobutene (BCB), tetramethylorthosilicate (TMOS), octamethylcyclotetrasiloxane (OMCTS), hexamethyldisiloxane (HMDS), trimethylsilyl borate (TMSB), diacetoxyditertiarybutosiloxane (DADBS), trimethylsilil phosphate (TMSP), polytetrafluoroethylene (PTFE), tonen silazene (TOSZ), fluoride silicate glass (FSG), polyimide nanofoams such as polypropylene oxide, carbon doped silicon oxide (CDO), organo silicate glass (OSG), SiLK, amorphous fluorinated carbon, silica aerogels, silica xerogels, mesoporous silica, or a combination thereof, but is not limited thereto.

The source/drain contact 170 may be disposed on the source/drain pattern 150 (e.g., see FIG. 2). The source/drain contact 170 may penetrate (i.e., extend into) the first interlayer insulating layer 190 and the etch stop layer 185. The source/drain contact 170 may be connected (e.g., electrically connected) to the source/drain pattern 150.

A contact silicide layer 175 may be disposed between the source/drain contact 170 and the source/drain pattern 150.

The source/drain contact 170 may contain a conductive material, e.g., at least one of metal, metal nitride, metal carbonitride, a two-dimensional (2D) material, or a conductive semiconductor material. The contact silicide layer 175 may include a metal silicide material.

Although it is illustrated that the source/drain contact 170 is a single layer, the present disclosure is not limited thereto. For example, the source/drain contact 170 may include a contact barrier layer and a contact filling layer that fills a space defined by the contact barrier layer.

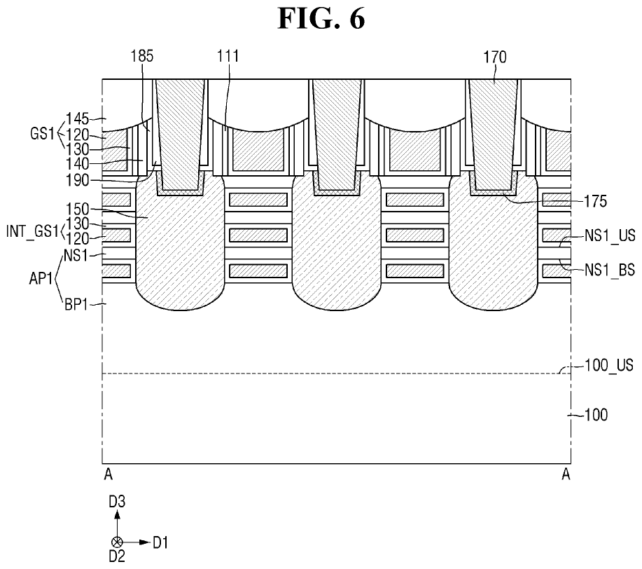

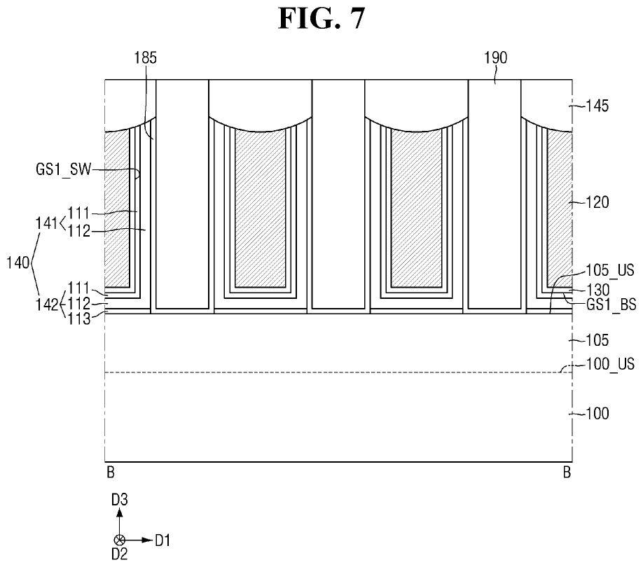

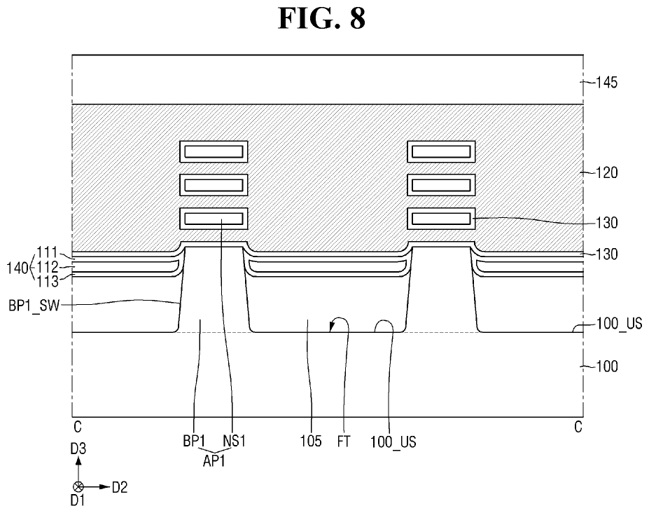

FIGS. 6 to 8 are diagrams illustrating a semiconductor device according to some embodiments. For simplicity of description, the following description will focus on differences from the description above with reference to FIGS. 1 to 5. For reference, FIG. 6 is a cross-sectional view taken along line A-A of FIG. 1. FIG. 7 is a cross-sectional view taken along line B-B of FIG. 1. FIG. 8 is a cross-sectional view taken along line C-C of FIG. 1.

Referring to FIGS. 6 to 8, in a semiconductor device according to some embodiments, the gate spacer 140 may include a first insulating layer 111, a second insulating layer 112, and a third insulating layer 113. The description of the first portion 141 and the second portion 142 of the gate spacer 140 is the same as described above.

The first insulating layer 111 may surround the gate structure GS1. The first insulating layer 111 may be disposed on the sidewall GS1_SW and the bottom surface GS1_BS of the gate structure GS1 (e.g., see FIG. 7). The first insulating layer 111 may be disposed on the gate insulating layer 130. For example, the first insulating layer 111 may be in contact with the gate structure GS1. The first insulating layer 111 may be disposed in the first portion 141 and the second portion 142 of the gate spacer 140.

The first insulating layer 111 may include, for example, at least one of silicon (Si), silicon nitride (SiN), silicon oxide (SiO₂), or silicon oxynitride (SiON).

The second insulating layer 112 may be disposed on the first insulating layer 111. The second insulating layer 112 may surround the gate structure GS1. The second insulating layer 112 may be disposed above the sidewall GS1_SW and the bottom surface GS1_BS of the gate structure GS1. The second insulating layer 112 may be disposed along the sidewall GS1_SW and the bottom surface GS1_BS of the gate structure GS1. The second insulating layer 112 may be disposed on the etch stop layer 185. The second insulating layer 112 may be disposed between the first insulating layer 111 and the third insulating layer 113. The second insulating layer 112 may be disposed in the first portion 141 and the second portion 142 of the gate spacer 140.

The second insulating layer 112 may include, for example, at least one of silicon nitride (SiN), silicon oxynitride (SiON), silicon oxide (SiO₂), silicon oxycarbonitride (SiOCN), silicon boron nitride (SiBN), silicon oxyboron nitride (SiOBN), silicon oxycarbide (SiOC) or a combination thereof. In some embodiments, the first insulating layer 111 and the second insulating layer 112 may include different materials.

The third insulating layer 113 may be disposed on the second insulating layer 112. The third insulating layer 113 may be disposed along the top surface 105_US of the field insulating layer 105 (e.g., see FIG. 7). For example, the third insulating layer 113 may be between the second insulating layer 112 and the field insulating layer 105. The third insulating layer 113 may include the same material as the first insulating layer 111. The first insulating layer 111 may be connected to the third insulating layer 113 on the sidewall BP1_SW of the lower pattern BP1 (e.g., see FIG. 8).

The third insulating layer 113 may include, for example, at least one of silicon (Si), silicon nitride (SiN), silicon oxide (SiO₂), or silicon oxynitride (SiON).

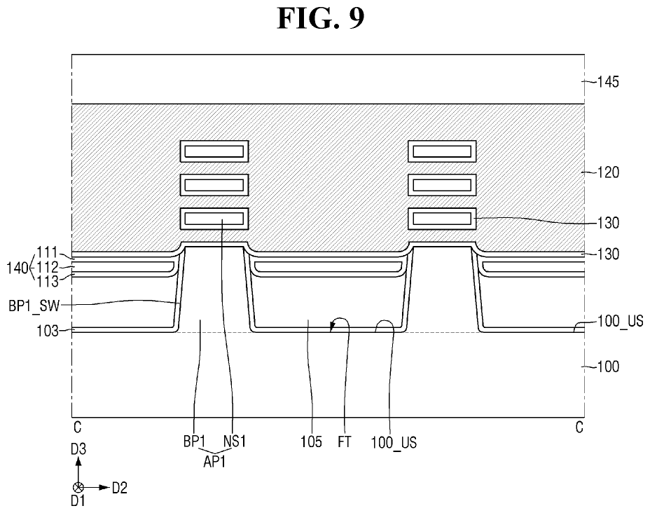

FIG. 9 is a diagram illustrating a semiconductor device according to some embodiments. For simplicity of description, the following description will focus on differences from the description above with reference to FIGS. 1 to 8.

Referring to FIG. 9, a semiconductor device according to some embodiments may include a liner layer 103 disposed along the sidewall and the bottom surface of the field trench FT. The liner layer 103 may be disposed along the top surface 100_US of the substrate 100 and the sidewall BP1_SW of the lower pattern BP1. The liner layer 103 may completely cover the sidewall BP1_SW of the lower pattern BP1. However, the present disclosure is not limited thereto. Unlike the drawing, the liner layer 103 may cover a part of the sidewall BP1_SW of the lower pattern BP1. The gate spacer 140 may cover the remainder of the sidewall BP1_SW of the lower pattern BP1.

The liner layer 103 may include, for example, at least one of silicon (Si), silicon nitride (SiN), silicon oxide (SiO₂), or silicon oxynitride (SiON).

The field insulating layer 105 may be disposed on the liner layer 103. The first insulating layer 111 and the third insulating layer 113 may be disposed on the liner layer 103. In some embodiments, the boundary between the first insulating layer 111 and the third insulating layer 113, and the liner layer 103 may not be distinguished.

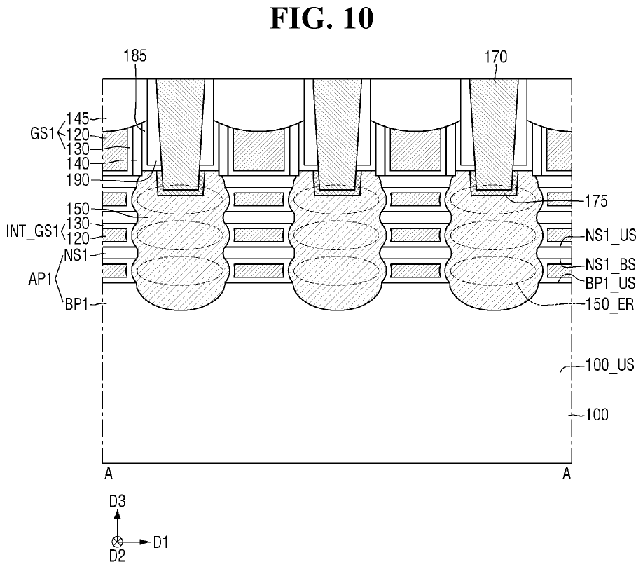

FIG. 10 is a diagram illustrating a semiconductor device according to some embodiments. For simplicity of description, the following description will focus on differences from the description above with reference to FIGS. 1 to 5.

Referring to FIG. 10, the sidewall of the first source/drain pattern 150 may have a wavy shape. The source/drain pattern 150 may include a plurality of width expansion regions 150_ER. The width expansion region 150_ER of each source/drain pattern 150 may be defined above the top surface BP1_US of the lower pattern BP1.

The width expansion region 150_ER of the source/drain pattern 150 may be defined between the sheet patterns NS1 that are adjacent in the third direction D3. The width expansion region 150_ER of the source/drain pattern 150 may be defined between the lower pattern BP1 and the sheet pattern NS1. The width expansion region 150_ER of the source/drain pattern 150 may be defined between the inner gate structures INTI_GS1 that are adjacent in the first direction D1.

The width expansion region 150_ER of each source/drain pattern 150 may include a portion whose width in the first direction D1 increases and a portion whose width in the first direction D1 decreases, as moving away from the top surface BP1_US of the lower pattern BP1 (e.g., moving away in the third direction D3). For example, the width of the width expansion region 150_ER of the source/drain pattern 150 in the first direction D1 may increase and then decrease as moving away from the top surface BP1_US of the lower pattern BP1.

The widths of the width expansion regions 150_ER of the respective source/drain patterns 150 in the first direction D1 are shown as being the same, but the present disclosure is not limited thereto.

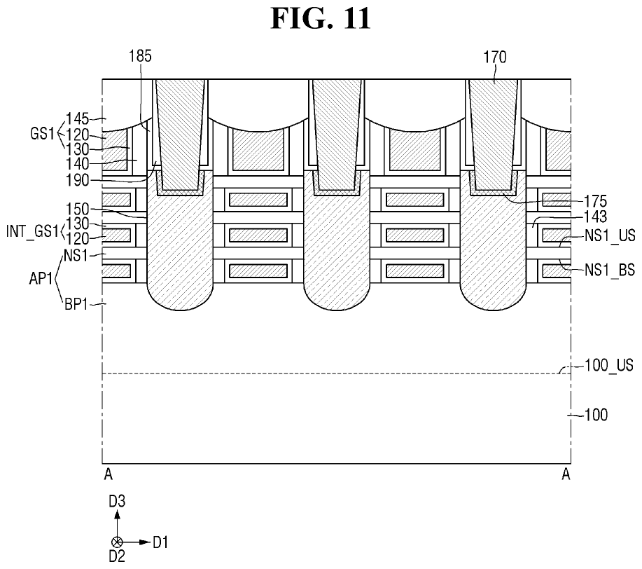

FIG. 11 is a diagram illustrating a semiconductor device according to some embodiments. For simplicity of description, the following description will focus on differences from the description above with reference to FIGS. 1 to 5.

Referring to FIG. 11, the semiconductor device according to some embodiments may further include an inner spacer 143 disposed between the gate structure GS1 and the source/drain pattern 150.

The inner spacer 143 may be disposed between the inner gate structure INT_GS1 and the source/drain pattern 150. The sidewall of the source/drain recess may be defined by the inner spacer 143.

The inner spacer 143 may be in contact with the inner gate structure INT_GS1. The inner spacer 143 may be in contact with the source/drain pattern 150.

The inner spacer 143 may include, for example, at least one of silicon nitride (SiN), silicon oxynitride (SiON), silicon oxide (SiO₂), silicon oxycarbonitride (SiOCN), silicon boron nitride (SiBN), silicon oxyboron nitride (SiOBN), silicon oxycarbide (SiOC) or a combination thereof.

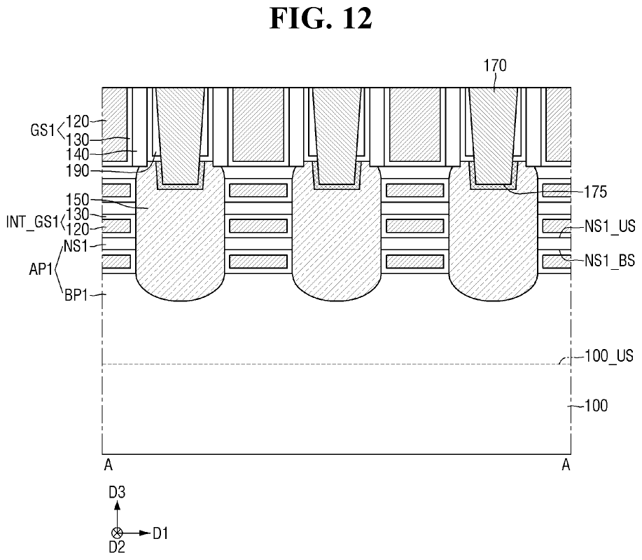

FIG. 12 is a diagram illustrating a semiconductor device according to some embodiments. For simplicity of description, the following description will focus on differences from the description above with reference to FIGS. 1 to 5.

Referring to FIG. 12, a semiconductor device according to some embodiments may not include the gate capping pattern 145. The gate structure GS1 may include the gate electrode 120 and the gate insulating layer 130. Unlike FIG. 2, the gate capping pattern 145 may not be disposed at the top portion of the gate structure GS1.

The top surface of the gate electrode 120 may be disposed on the same plane as the top surface of the gate spacer 140. The top surface of the gate electrode 120 may be disposed on the same plane as the top surface of the first interlayer insulating layer 190.

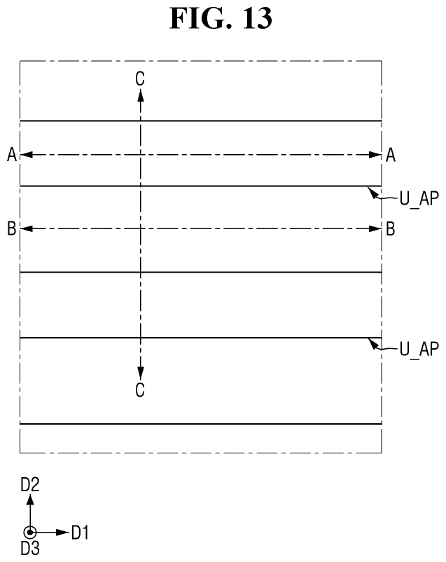

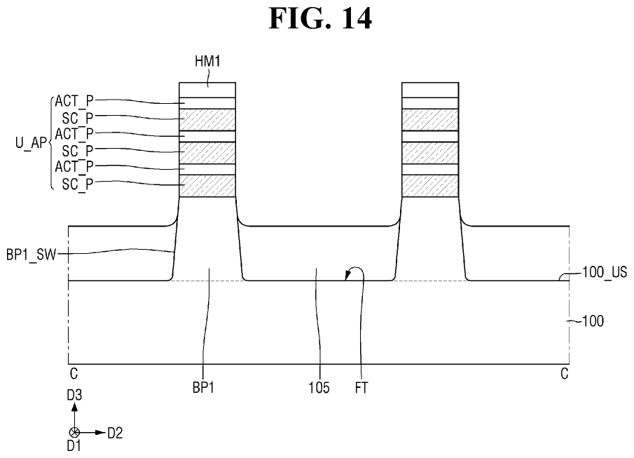

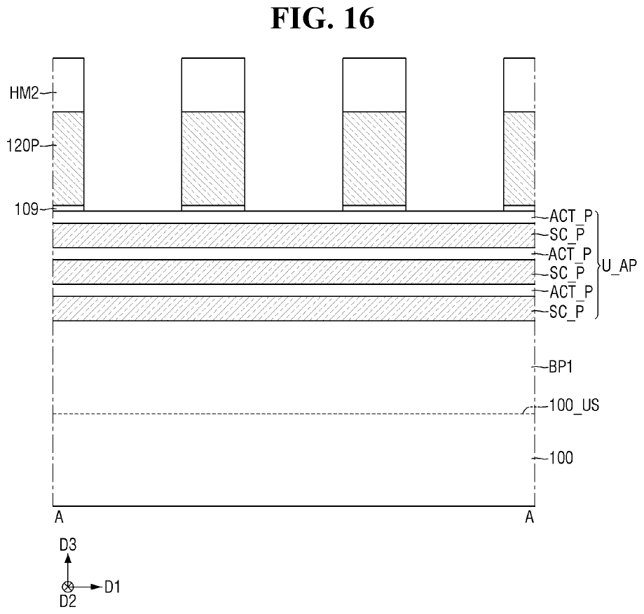

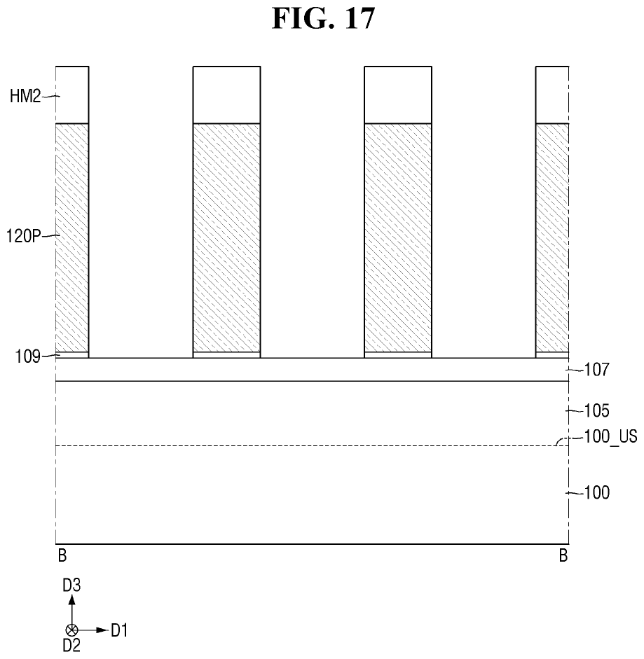

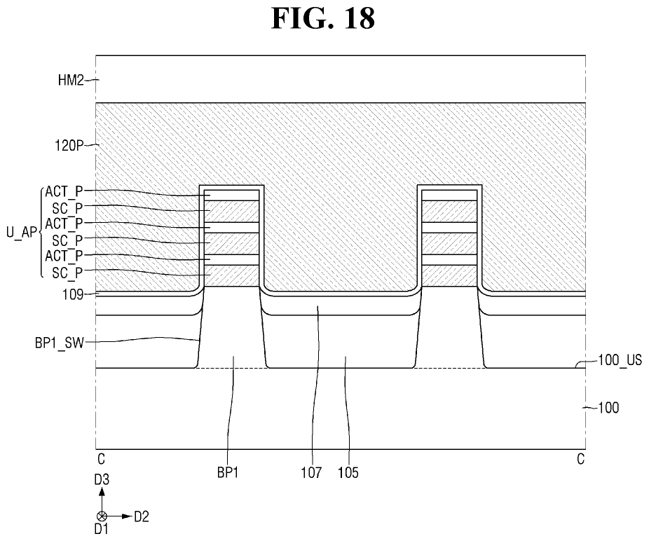

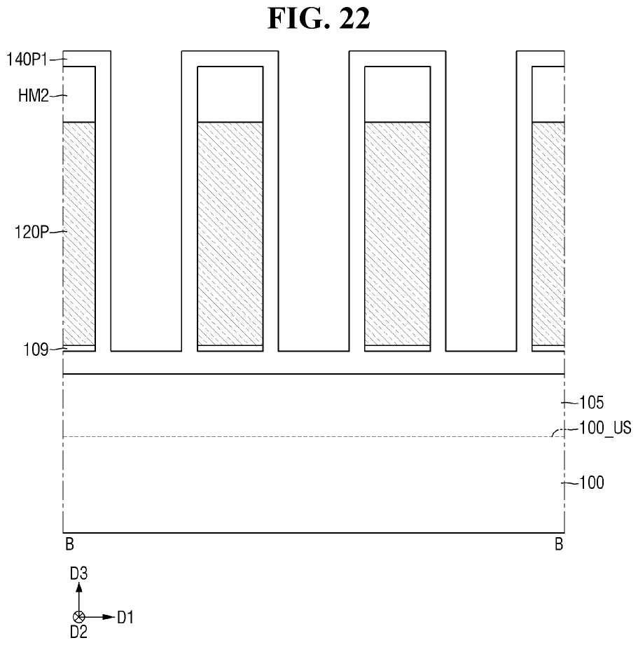

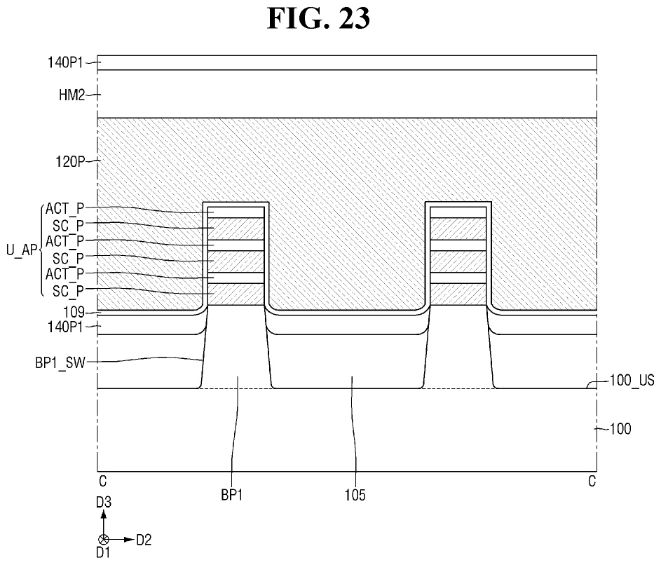

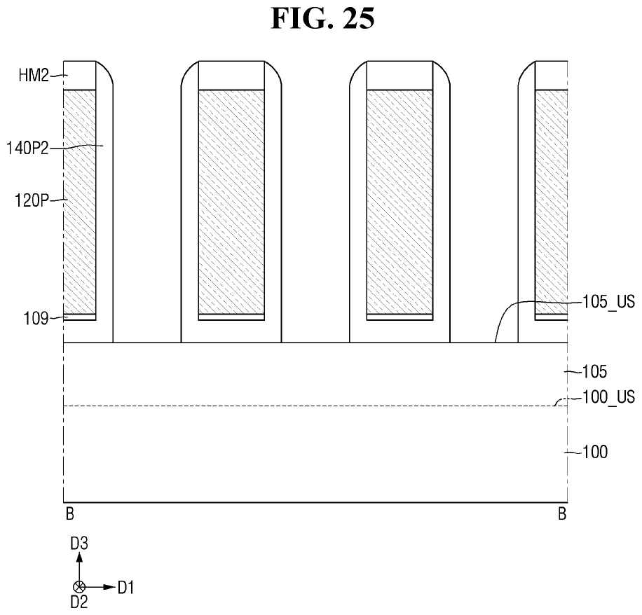

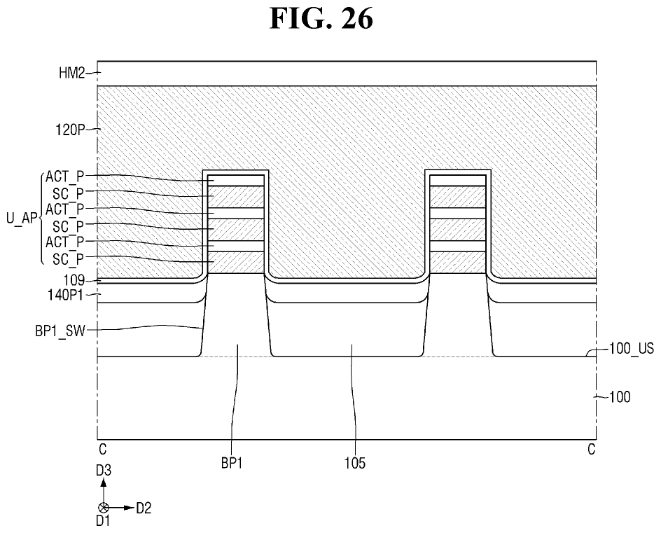

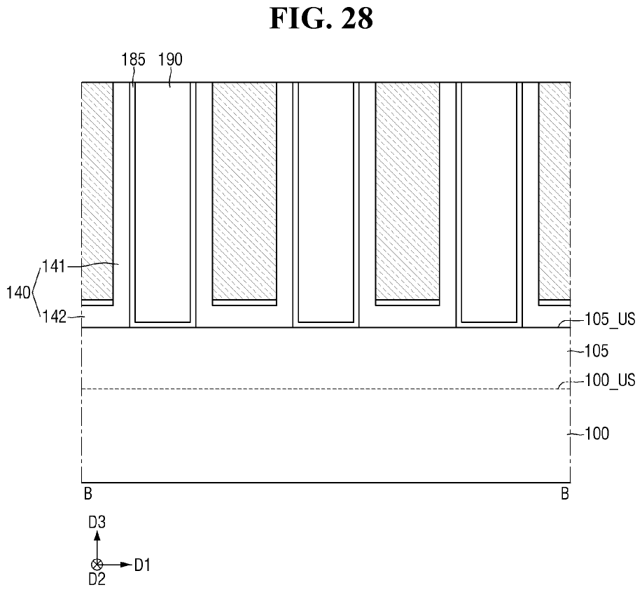

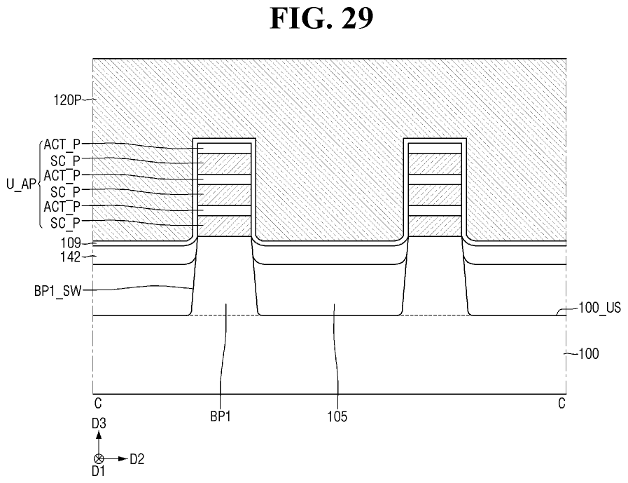

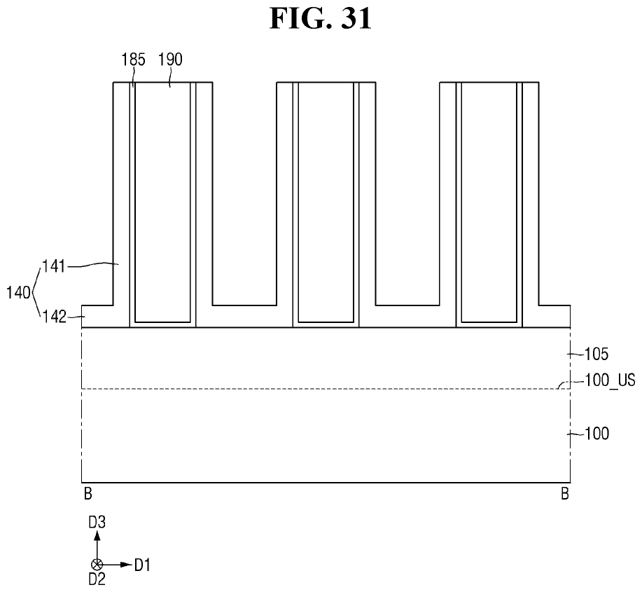

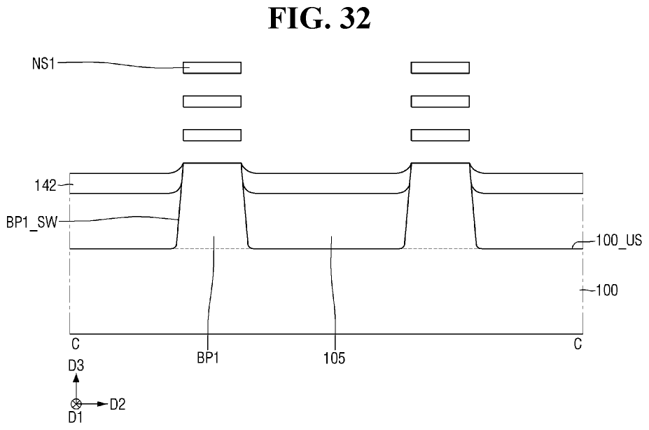

FIGS. 13 to 32 are diagrams illustrating the intermediate steps of a method for fabricating a semiconductor device according to some embodiments. FIG. 13 is an example plan view illustrating a method for fabricating a semiconductor device according to some embodiments. FIGS. 16, 21, 24, 27, and 30 are cross-sectional views taken along line A-A of FIG. 13. FIGS. 17, 19, 22, 25, 28, and 31 are cross-sectional views taken along line B-B of FIG. 13. FIGS. 14, 15, 18, 20, 23, 26, 29, and 32 are cross-sectional views taken along line C-C of FIG. 13.

Referring to FIGS. 13 and 14, the lower pattern BP1, a pattern structure U_AP, and the field insulating layer 105 may be formed on the substrate 100.

Specifically, the lower pattern BP1 may be formed on the substrate 100, and the pattern structure U_AP may be formed on the lower pattern BP1. The pattern structure U_AP may extend in the first direction D1. The pattern structures U_AP may be spaced apart from each other in the second direction D2. The pattern structure U_AP may include a sacrificial pattern SC_P and an active pattern ACT_P that are alternately stacked.

The pattern structure U_AP may be formed on the stacked pattern using a first hard mask pattern HM1 as an etch mask. While the pattern structure U_AP is being formed, the substrate 100 is partially etched, so that the lower pattern BP1 may be formed. The pattern structure U_AP is formed on the lower pattern BP1.

Subsequently, the field insulating layer 105 may be formed in the field trench FT. The field insulating layer 105 may be formed by forming a first insulating material in the field trench FT, and removing an upper portion of the first insulating material. The field insulating layer 105 may cover a part of the sidewall BP1_SW of the lower pattern BP1.

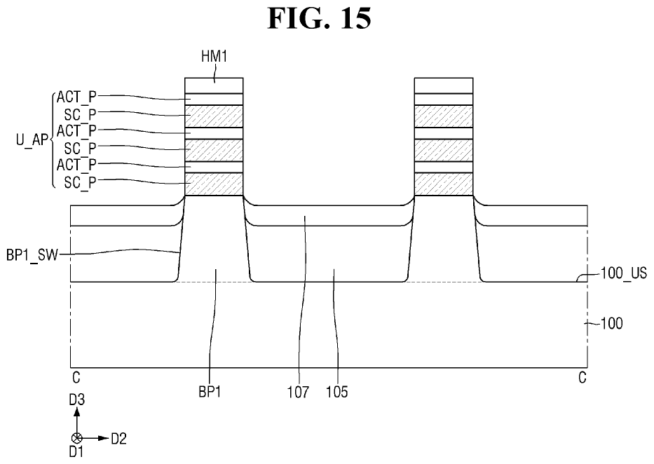

Referring to FIG. 15, a sacrificial liner layer 107 may be formed on the field insulating layer 105.

Specifically, the sacrificial liner layer 107 may be formed by depositing a second insulating material on the field insulating layer 105, and removing an upper portion of the second insulating material. The second insulating material may be a material having an etch selectivity with respect to the field insulating layer 105.

The sacrificial liner layer 107 may be disposed on the top surface 105_US of the field insulating layer 105 and the sidewall BP1_SW of the lower pattern BP1. The sacrificial liner layer 107 and the field insulating layer 105 may completely cover the sidewall BP1_SW of the lower pattern BP1.

Subsequently, the first hard mask pattern HM1 may be removed to expose the top surface of the pattern structure U_AP.

Referring to FIGS. 16 to 18, a first insulating liner layer 109, a dummy gate electrode 120P, and a second hard mask pattern HM2 may be formed on the pattern structure U_AP.

The first insulating liner layer 109 may cover the top surface of the sacrificial liner layer 107 and a part of the pattern structure U_AP. The first insulating liner layer 109 may expose a part of the pattern structure U_AP.

The dummy gate electrode 120P may be disposed on the first insulating liner layer 109. The dummy gate electrode 120P may be elongated in the second direction D2. The second hard mask pattern HM2 may be disposed on the dummy gate electrode 120P.

The dummy gate electrode 120p may include, for example, polysilicon, but the present disclosure is not limited thereto. The second hard mask pattern HM2 may include, for example, silicon nitride, but is not limited thereto.

The dummy gate electrode 120P may be formed by using the second hard mask pattern HM2 as an etch mask. For example, polysilicon may be deposited on the pattern structure U_AP, and patterned using the second hard mask pattern HM2 as an etch mask. The patterned polysilicon may be the dummy gate electrode 120P.

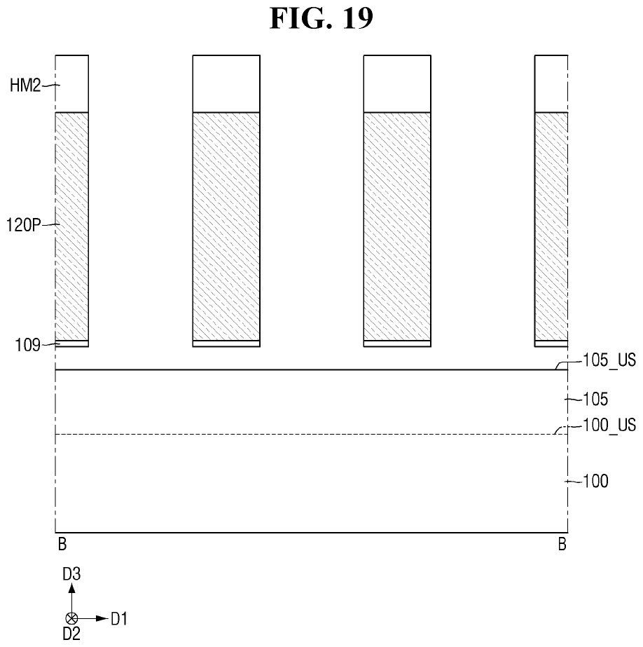

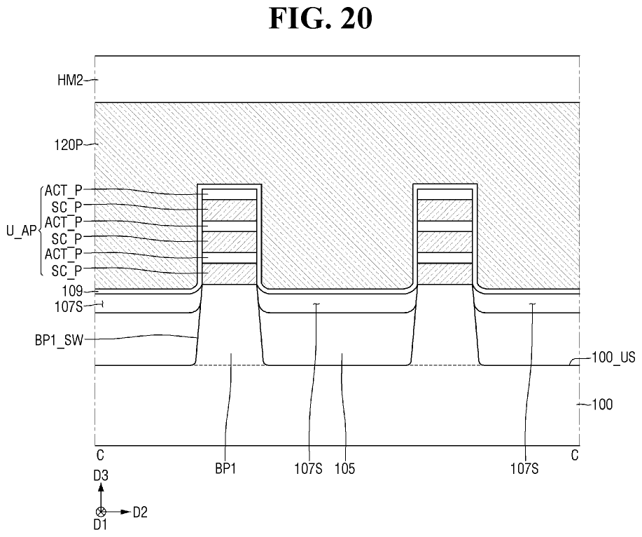

Referring to FIGS. 19 and 20, the sacrificial liner layer 107 may be removed to expose the field insulating layer 105.

Specifically, the sacrificial liner layer 107 may be removed, and the top surface 105_US of the field insulating layer 105 may be exposed. The sacrificial liner layer 107 may be removed to form a first space 107S between the field insulating layer 105 and the first insulating liner layer 109. The sidewall BP1_SW of the lower pattern BP1 may be partially exposed by the first space 107S.

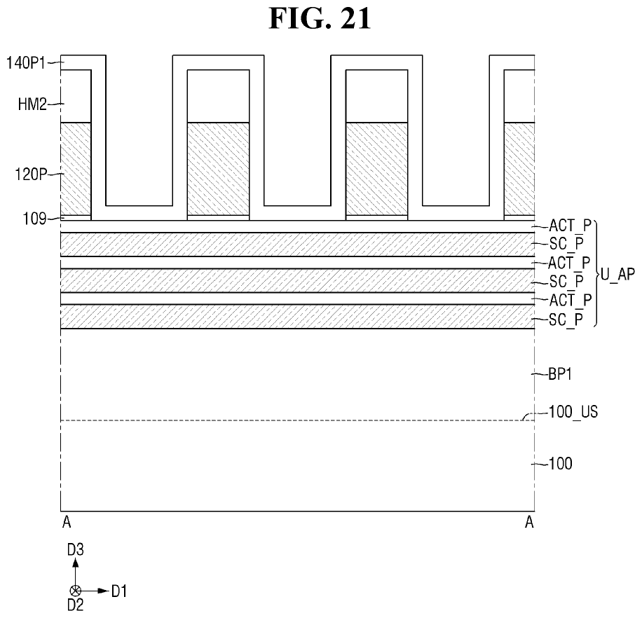

Referring to FIGS. 21 to 23, a first pre-gate spacer 140P1 may be formed on the pattern structure U_AP and the field insulating layer 105.

Specifically, the first pre-gate spacer 140P1 may be disposed along the profile of the second hard mask pattern HM2 and the dummy gate electrode 120P. The first pre-gate spacer 140P1 may cover the exposed top surface of the pattern structure U_AP and the exposed top surface 105_US of the field insulating layer 105. The first pre-gate spacer 140P1 may fill the first space 107S.

Referring to FIGS. 24 to 26, a second pre-gate spacer 140P2 and the source/drain recess 150R may be formed using the second hard mask pattern HM2 as a mask.

A part of the source/drain recess 150R may be formed in the lower pattern BP1. The source/drain recess 150R may be formed on at least one side of the dummy gate electrode 120P. The source/drain recess 150R may expose the active pattern ACT_P and the sacrificial pattern SC_P. In this case, the thickness of the second hard mask pattern HM2 may be decreased.

The upper surface 105_US of the field insulating layer 105 may be partially exposed by forming the second pre-gate spacer 140P2. The second pre-gate spacer 140P2 may be disposed between the dummy gate electrode 120P and the field insulating layer 105.

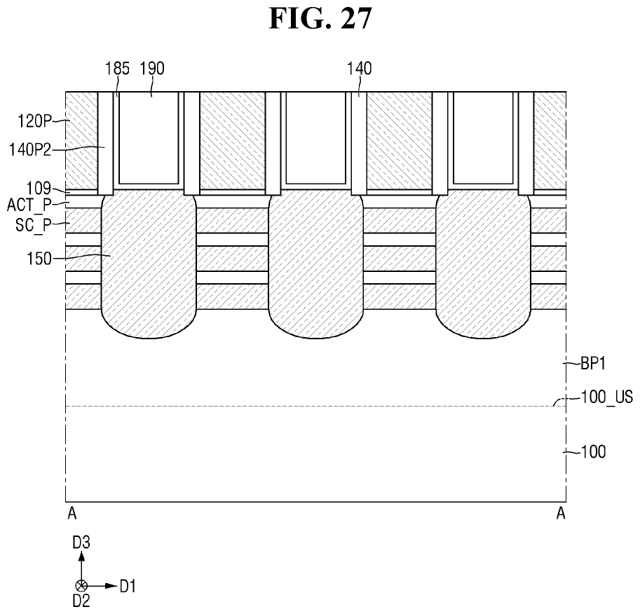

Referring to FIGS. 27 to 29, the source/drain pattern 150, the etch stop layer 185, and the first interlayer insulating layer 190 may be formed.

Specifically, the source/drain pattern 150 may fill the source/drain recess 150R. The source/drain pattern 150 may be formed on at least one side of the dummy gate electrode 120P. The source/drain pattern 150 may be in contact with the active pattern ACT_P and the sacrificial pattern SC_P.

Then, the etch stop layer 185 and the first interlayer insulating layer 190 may be sequentially formed on the source/drain pattern 150.

The etch stop layer 185 may be formed along the profile of the second pre-gate spacer 140P2 (e.g., see FIG. 27) and the top surface 105_US of the field insulating layer 105. The first interlayer insulating layer 190 may be formed on the etch stop layer 185.

While forming the etch stop layer 185 and the first interlayer insulating layer 190, the second hard mask pattern HM2 may be removed to expose a top surface of the dummy gate electrode 120P. In addition, an upper portion of the second pre-gate spacer 140P2 may be removed to form the gate spacer 140. The gate spacer 140 may include the first portion 141 and the second portion 142.

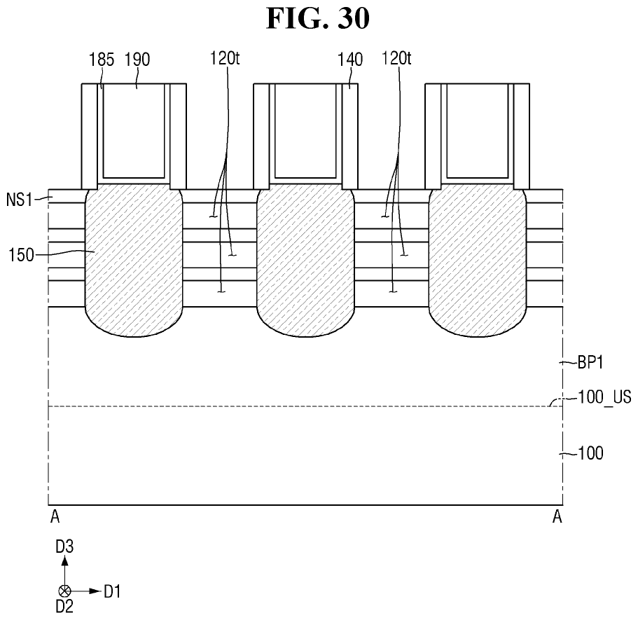

Referring to FIGS. 30 to 32, the dummy gate electrode 120P, the first insulating liner layer 109, and the sacrificial pattern SC_P may be removed.

Specifically, the exposed dummy gate electrode 120P may be removed. In this case, the first insulating liner layer 109 may not be removed. When the dummy gate electrode 120P is removed, the first insulating liner layer 109 may protect the active pattern ACT_P and the sacrificial pattern SC_P.

Subsequently, the first insulating liner layer 109 and the sacrificial pattern SC_P may be removed. The first insulating liner layer 109 and the sacrificial pattern SC_P may be sequentially removed. The sacrificial pattern SC_P may be removed to form the sheet pattern NS1 and a gate trench 120t.

Then, referring to FIGS. 2 to 5, the gate electrode 120 may be formed on the gate trench 120t and the sheet pattern NS1. The gate capping pattern 145 may be formed on the gate electrode 120. The contact silicide layer 175 and the source/drain contact 170 may be formed on the source/drain pattern 150.

As used herein, the terms “comprises”, “comprising”, “includes”, “including”, “has”, “having” and any other variations thereof specify the presence of the stated features, steps, operations, elements, components, and/or groups but do not preclude the presence or addition of one or more other features, steps, operations, elements, components, and/or groups thereof.

In concluding the detailed description, those skilled in the art will appreciate that many variations and modifications may be made to the example embodiments without substantially departing from the principles of the present inventive concepts. Therefore, the disclosed example embodiments are used in a generic and descriptive sense only and not for purposes of limitation.

What is claimed is:

1. A semiconductor device comprising:
an active pattern that comprises a lower pattern extending in a first direction on a substrate and a sheet pattern on the lower pattern;
a field insulating layer that defines the active pattern on the substrate;
a gate structure on the lower pattern and comprising a gate insulating layer and a gate electrode, the gate electrode extending in a second direction perpendicular to the first direction;
a gate spacer at least partially surrounding the gate structure and comprising a first portion on a sidewall of the gate structure and a second portion on a bottom surface of the gate structure; and
a source/drain pattern on the lower pattern and in contact with the sheet pattern.

2. The semiconductor device of claim 1, wherein the gate spacer comprises a first insulating layer in contact with the gate structure and a second insulating layer at least partially surrounding the first insulating layer.

3. The semiconductor device of claim 2, wherein the gate spacer further comprises a third insulating layer between the second insulating layer and the field insulating layer, and
wherein the first insulating layer and the third insulating layer comprise a same material.

4. The semiconductor device of claim 1, wherein the second portion of the gate spacer is between the field insulating layer and the gate structure.

5. The semiconductor device of claim 1, wherein the second portion of the gate spacer is on a sidewall of the lower pattern.

6. The semiconductor device of claim 1, wherein the second portion of the gate spacer is free of overlap with the sheet pattern in a third direction perpendicular to the second direction.

7. The semiconductor device of claim 1, further comprising a first interlayer insulating layer on the field insulating layer and the source/drain pattern,
wherein a lower portion of the first interlayer insulating layer overlaps the second portion of the gate spacer in the first direction.

8. The semiconductor device of claim 7, wherein the second portion of the gate spacer is not between the first interlayer insulating layer and the field insulating layer.

9. The semiconductor device of claim 1, wherein the field insulating layer is on a first portion of a sidewall of the lower pattern, and the second portion of the gate spacer is on a second portion of the sidewall of the lower pattern, and
wherein the first and second portions of the sidewall of the lower pattern are connected to each other.

10. The semiconductor device of claim 1, further comprising a liner layer on a top surface of the substrate and a sidewall of the lower pattern,
wherein the field insulating layer is on the liner layer.

11. The semiconductor device of claim 1, wherein the gate structure comprises a gate capping pattern on a top surface of the gate electrode.

12. The semiconductor device of claim 1, wherein the sheet pattern comprises a plurality of sheet patterns spaced apart from each other,
wherein the gate structure comprises an inner gate structure between the lower pattern and the sheet pattern and between ones of the plurality of sheet patterns that are adjacent to each other,
wherein the inner gate structure comprises the gate electrode and the gate insulating layer, and
wherein the semiconductor device further comprises an inner spacer between the inner gate structure and the source/drain pattern.

13. A semiconductor device comprising:
a plurality of active patterns, each of the active patterns comprising a lower pattern extending in a first direction on a substrate and a sheet pattern on the lower pattern;
a field trench defined by a top surface of the substrate and a sidewall of the lower pattern;
a field insulating layer in the field trench;
a gate structure on the lower pattern and comprising a gate insulating layer and a gate electrode, the gate electrode extending in a second direction perpendicular to the first direction;
a gate spacer comprising a first portion that extends in a third direction perpendicular to the second direction along a sidewall of the gate structure and a second portion that extends in the first direction along a top surface of the field insulating layer;
a source/drain pattern on the lower pattern and in contact with the sheet pattern; and
a first interlayer insulating layer on the field insulating layer and the source/drain pattern and on one side of the gate structure.

14. The semiconductor device of claim 13, wherein the first interlayer insulating layer is free of overlap with the gate spacer in the third direction.

15. The semiconductor device of claim 13, wherein the second portion of the gate spacer is between the gate structure and the field insulating layer.

16. The semiconductor device of claim 13, wherein the gate spacer comprises a first insulating layer in contact with the gate structure and a second insulating layer at least partially surrounding the first insulating layer, and
wherein the first insulating layer and the second insulating layer comprise different materials.

17. The semiconductor device of claim 16, wherein the gate spacer further comprises a third insulating layer between the second insulating layer and the field insulating layer, and
wherein the first insulating layer and the third insulating layer comprise a same material.

18. The semiconductor device of claim 13, wherein the field insulating layer comprises a first region that overlaps the gate structure in the third direction, and a second region that is free of overlap with the gate structure in the third direction, and
wherein a thickness of the first region of the field insulating layer in the third direction is greater than a thickness of the second region of the field insulating layer in the third direction.

19. The semiconductor device of claim 13, further comprising a liner layer on a top surface of the substrate and a sidewall of the lower pattern,
wherein the field insulating layer is on the liner layer.

20. A semiconductor device comprising:
an active pattern that comprises a lower pattern extending in a first direction on a substrate and a sheet pattern on the lower pattern;
a field insulating layer that defines the active pattern on the substrate;
a gate structure on the lower pattern and comprising a gate insulating layer and a gate electrode, the gate electrode extending in a second direction perpendicular to the first direction;
a gate spacer at least partially surrounding the gate structure and comprising a first portion on a sidewall of the gate structure and a second portion on a bottom surface of the gate structure;
a source/drain pattern on the lower pattern and in contact with the sheet pattern; and
a first interlayer insulating layer on the field insulating layer and the source/drain pattern and extending in the second direction,
wherein the second portion of the gate spacer is between the field insulating layer and the gate structure, and is not between the field insulating layer and the first interlayer insulating layer.
